(19) United States
(12) Patent Application Publication
(10) Pub. No.: US 2026/0023909 A1
(43) Pub. Date: Jan. 22, 2026

(54) TRANSLATING FLAT TRANSISTOR SHAPES INTO TRANSISTOR PCELLS

(71) Applicant: INTERNATIONAL BUSINESS MACHINES CORPORATION, ARMONK, NY (US)

(72) Inventors: Tobias Werner, Weil im Schoenbuch (DE); Vishniu KUPPUSWAMY SREENIVASAN, Vellore (IN); Jan Niklas Stegmaier, Sindelfingen (DE); Davide Fiorentini, Sindelfingen (DE)

(21) Appl. No.: 18/809,908

(22) Filed: Aug. 20, 2024

(30) Foreign Application Priority Data
Jul. 22, 2024 (GB) 2410690.8

(51) Int. Cl. G06F 30/337; G06F 30/327

(52) U.S. Cl. CPC G06F 30/337; G06F 30/327

(57) ABSTRACT

A method for translating flat transistor shapes into transistor pcells during a hardware design process of a semiconductor chip comprising transistors. A netlist and a first layout of the semiconductor chip can be extracted, wherein the netlist and the first layout comprise parameters defining properties of transistors of the first layout and connectivity of the transistors of the first layout. Based on the netlist and the first layout, power connections, tracing signal connections, and shared contacts of respective ones of transistors of the first layout can be detected. A permute state of respective ones of transistors of the first layout can be established. Transistor pcells can be defined based on the permute state for respective transistors of the first layout. Flat transistor shapes of the transistors within the first layout can be removed and respective ones of the transistor pcells can be placed into the first layout.

### BACKGROUND

Transistor level layouts are essential to build processor chips. An example for a transistor level layout could be a standard logic gate like a NAND2 or a more complex layout like a LATCH (storage element). The layout of a transistor can be represented by flat shapes, where a transistor is at least defined by a gate oxide (RX), a gate (PC), and a contact to active (CA) or by a so-called transistor parameterized cell (pcell), a parameterized object that builds the transistor shapes based on parameters and is used in the automated design of analog or digital integrated circuits.

### SUMMARY

A computer implemented method for translating flat transistor shapes into transistor pcells during a hardware design process of a semiconductor chip comprising transistors is proposed, the method comprising: extracting a netlist and a first layout of the semiconductor chip; receiving data from the netlist and the first layout comprising parameters defining the properties of the transistors as well as a connectivity of the transistors; based on the data from the first layout detecting power connections for each transistor of the first layout and tracing signal connections and shared contacts for each transistor of the first layout; establishing a permute state for each transistor of the first layout; defining transistor pcells from the data and the permute state for each transistor; and placing the transistor pcells in the first layout and removing the flat transistor shapes from the first layout.

The illustrative embodiments may further be used for a semiconductor chip for a computer system, comprising a plurality of transistors, designed by the computer implemented method for translating flat transistor shapes into transistor pcells during a hardware design process.

Further, a computer system for translating flat transistor shapes into transistor pcells during a hardware design process of a semiconductor chip comprising transistors is proposed, comprising a computer processing unit storing computer executable instructions to perform the method, comprising: extracting a netlist and a first layout of the semiconductor chip; receiving data from the netlist and the first layout comprising parameters defining the properties of the transistors as well as a connectivity of the transistors; based on the data from the first layout detecting power connections for each transistor of the first layout and tracing signal connections and shared contacts for each transistor of the first layout; establishing a permute state for each transistor of the first layout; defining transistor pcells from the data and the permute state for each transistor; and placing the transistor pcells in the first layout and removing the flat transistor shapes from the first layout.

Further, a computer program product for translating flat transistor shapes into transistor pcells during a hardware design process of a semiconductor chip comprising transistors is proposed, the computer program product comprising a computer readable storage medium having program instructions embodied therewith, the program instructions executable by the computer system to cause the computer system to perform the method, comprising: extracting a netlist and a first layout of the semiconductor chip; receiving data from the netlist and the first layout comprising parameters defining the properties of the transistors as well as a connectivity of the transistors; based on the data from the first layout detecting power connections for each transistor of the first layout and tracing signal connections and shared contacts for each transistor of the first layout; establishing a permute state for each transistor of the first layout; defining transistor pcells from the data and the permute state for each transistor; and placing the transistor pcells in the first layout and removing the flat transistor shapes from the first layout.

Further, a data processing system for execution of a data processing program comprising computer readable program instructions for performing the method is proposed.

### BRIEF DESCRIPTION OF THE SEVERAL VIEWS OF THE DRAWINGS

The present invention together with the above-mentioned and other objects and advantages may best be understood from the following detailed description of the embodiments, but not restricted to the embodiments.

FIG. 1 depicts grouping neighboring gate electrodes of multi-gate flat transistor shapes of a netlist by a single transistor pcell with a corresponding number of gate electrodes, according to embodiments of the present disclosure.

FIG. 2 depicts a first permute state for a transistor pcell, according to embodiments of the present disclosure.

FIG. 3 depicts a second permute state for a transistor pcell, according to embodiments of the present disclosure.

FIG. 4 depicts a flow chart of the computer implemented method for translating flat transistor shapes into transistor pcells during a hardware design process of a semiconductor chip comprising transistors, according to embodiments of the present disclosure.

FIG. 5 depicts translating a position of a transistor pcell into a matrix comprising columns and rows, according to embodiments of the present disclosure.

FIG. 6 depicts performing a coordinate translation of a transistor pcell relative to a position of a gate electrode, according to embodiments of the present disclosure.

FIG. 7 depicts power connections of a transistor pcell layout, according to embodiments of the present disclosure.

FIG. 8 depicts configuring a shared contact between two transistors pcells with a same net connection, according to embodiments of the present disclosure.

FIG. 9 depicts tracing signal connections comprising tracing physical shapes to get connected transistor contacts, according to embodiments of the present disclosure.

FIG. 10 depicts an example embodiment of a data processing system for executing a method, according to embodiments of the present disclosure.

### DETAILED DESCRIPTION

In the drawings, like elements are referred to with equal reference numerals. The drawings are merely schematic representations, not intended to portray specific parameters of the invention. Moreover, the drawings are intended to depict only typical embodiments of the invention and therefore should not be considered as limiting the scope of the invention.

As discussed above, transistor level layouts are essential to build processor chips. An example for a transistor level layout could be a standard logic gate like a NAND2 or a more complex layout like a LATCH (storage element). The layout of a transistor can be represented by flat shapes, where a transistor is at least defined by a gate oxide (RX), a gate (PC), and a contact to active (CA) or by a so-called transistor parameterized cell (pcell), a parameterized object that builds the transistor shapes based on parameters and is used in the automated design of analog or digital integrated circuits.

At the beginning of a project often the transistor is represented with flat shapes due to either non-availability of a transistor pcell or deficiencies in the transistor layout generation, e.g. invalid dimensions and/or overlaps. Handling flat layouts is time consuming. Handling layouts that instantiate transistor pcells is less time consuming since transistor instances can be selected, parameters modified, and net connectivity can be visualized.

The illustrative embodiments described herein provide a computer implemented method for translating flat transistor shapes into transistor pcells during a hardware design process of a semiconductor chip comprising transistors is proposed, the method comprising: extracting a netlist and a first layout of the semiconductor chip; receiving data from the netlist and the first layout comprising parameters defining the properties of the transistors as well as a connectivity of the transistors; based on the data from the first layout detecting power connections for each transistor of the first layout and tracing signal connections and shared contacts for each transistor of the first layout; establishing a permute state for each transistor of the first layout; defining transistor pcells from the data and the permute state for each transistor; and placing the transistor pcells in the first layout and removing the flat transistor shapes from the first layout.

The illustrative embodiments may further be used for a semiconductor chip for a computer system, comprising a plurality of transistors, designed by the computer implemented method for translating flat transistor shapes into transistor pcells during a hardware design process.

According to an embodiment of the invention translation of flat transistor layouts into pcell layouts may be automated and with this allows a faster maintenance of transistor layouts. A pcell layout enables designers/layouters to quickly understand a layout since they can search for transistor instance names, show connectivity flightlines or highlight connected shapes to a transistor. If parameters are changed, the pcell layout enables to adapt the search for transistor instance names, to show connectivity. Therefore, the pcell layout is easily to maintain.

Manually migrating a flat transistor layout to a pcell layout, i.e. manually detecting transistor correspondence by comparing a schematic topology of the semiconductor chip with layout shapes and replacing flat shapes by transistor pcells, may be avoided. Favorably costs for the design process of a semiconductor chip may be reduced.

In an additional or alternative embodiment of the invention, a replacement of the flat transistor shapes in the first layout by transistor pcells may be performed, wherein the replacement is stored in a second layout. Favorably storing the replacement in the second layout may enable to make the management as well as the verification of the different layouts easier.

In an additional or alternative embodiment of the invention, the second layout may replace the first layout. Further layout processes may be performed on the pcell layout.

In an additional or alternative embodiment of the invention, parameters defining the properties of the transistor may comprise at least one of a position of the transistor in the first layout, a transistor type, a number of gate fingers, a channel width, a number of fins, a sheet width, a width to length ratio. Thus, essential design parameters of the transistor are covered by the pcell layout design.

In an additional or alternative embodiment of the invention, the connectivity of a transistor at least may comprise net connections of a gate electrode, and/or a drain electrode, and/or a source electrode of the transistor. Thus, essential design parameters of the transistor are covered by the pcell layout design.

In an additional or alternative embodiment of the invention, the permute state for each transistor pcell of the first layout may be detected comprising assigning a source electrode or a drain electrode as a left contact of a gate electrode based on at least one of power connections, shared contacts, net tracing in the first layout. The permute state of the transistor, necessary to identify possible connections of neighboring transistors, maybe favourable to replace flat shapes by a transistor pcell.

In an additional or alternative embodiment of the invention, drain electrodes and source electrodes of the transistor pcells may be placed in an alternating sequence. Thus, a flexible design for a layout of a whole semiconductor chip due to easier routing of connections to the transistor electrodes may be achieved.

In an additional or alternative embodiment of the invention, neighboring gate electrodes of multi-gate flat transistor shapes of the netlist may be grouped and represented by a single transistor pcell with a corresponding number of gate electrodes. Translation of a flat shapes layout into a pcell layout may favourably be achieved.

In an additional or alternative embodiment of the invention, a position of a transistor pcell may be translated into a matrix comprising columns and rows. Translation of a flat shapes layout into a pcell layout may favourably be achieved.

In an additional or alternative embodiment of the invention, a coordinate translation of a transistor pcell relative to a position of a gate electrode may be performed. In particular, a coordinate origin of a transistor pcell may be defined in a lower left corner position of a gate electrode. Thus, transistor pcells in layout may easily be generated.

In an additional or alternative embodiment of the invention, neighboring flat transistor shapes may be grouped with a same base name into a single transistor pcell. The pcell layout may easily be generated from an algorithm that gets executed on the pcell.

In an additional or alternative embodiment of the invention, dummy transistors in the first layout may be removed. A so-called dummy transistor may be identified by the fact that a source contact is equal to a drain contact in the net. It must be removed from the layout because it is a non-functional component.

In an additional or alternative embodiment of the invention, a transistor correspondence may be set between the first layout and a schematic topology of the semiconductor chip. Thus, verification of the pcell layout compared to the flat transistor layout may be facilitated.

In an additional or alternative embodiment of the invention, a shape connectivity may be set by routing connections to the contacts of the transistor pcells. Design of the pcell layout may be facilitated.

In an additional or alternative embodiment of the invention, it may be checked at a source-drain connection if there is a power connection to a power line at a top boundary or a bottom boundary of the transistor pcell. Verification of the pcell design may be performed by inspecting source-drain connections to power connections to a neigboring power line.

In an additional or alternative embodiment of the invention, the shared contact between two transistors pcells may be configured with a same net connection. Efficiency of the net connections may be achieved.

In an additional or alternative embodiment of the invention, tracing signal connections may comprise tracing physical shapes to get connected transistor contacts.

Circuit design environments may provide tracing capabilities for this purpose being able to track signal connections in a way to realize if there are connected transistor contacts.

Further, a semiconductor chip for a computer system comprising a plurality of transistors is proposed, designed by a computer implemented method for translating flat transistor shapes into transistor pcells during a hardware design process.

Design of the semiconductor chip may be facilitated by automated translation of flat transistor layouts into pcell layouts and with this allows a faster maintenance of transistor layouts. A pcell layout enables designers/layouters to quickly understand a layout since they can search for transistor instance names, show connectivity flightlines or hilight connected shapes to a transistor. If parameters are changed the layout adapts search for instance names, show connectivity, therefore being easily to maintain.

Favorably costs for the design process of the semiconductor chip may be reduced.

In an additional or alternative embodiment of the invention, each transistor pcell may be configured with a source electrode or a drain electrode may be assigned as a left contact of a gate electrode based on at least one of power connections, shared contacts, net tracing in the first layout. A permute state of the transistor may favourably be detected.

In an additional or alternative embodiment of the invention, drain electrodes and source electrodes of the transistor pcells may be placed in an alternating sequence. Thus, a flexible design for a layout of a whole semiconductor chip may be achieved.

In an additional or alternative embodiment of the invention, neighboring flat transistor shapes with a same base name may be grouped into a single transistor pcell. The pcell layout may easily be implemented from the flat shape layout.

Further, a computer system for translating flat transistor shapes into transistor pcells during a hardware design process of a semiconductor chip comprising transistors is proposed, comprising a computer processing unit storing computer executable instructions to perform the method, comprising: extracting a netlist and a first layout of the semiconductor chip; receiving data from the netlist and the first layout comprising parameters defining the properties of the transistors as well as a connectivity of the transistors; based on the data from the first layout detecting power connections for each transistor of the first layout and tracing signal connections and shared contacts for each transistor of the first layout; establishing a permute state for each transistor of the first layout; defining transistor pcells from the data and the permute state for each transistor; and placing the transistor pcells in the first layout and removing the flat transistor shapes from the first layout.

According to an embodiment of the invention translation of flat transistor layouts into pcell layouts may be facilitated and with this allows a faster maintenance of transistor layouts. Favorably costs for the design process of a semiconductor chip may be reduced.

Further, a computer program product for translating flat transistor shapes into transistor pcells during a hardware design process of a semiconductor chip comprising transistors is proposed, the computer program product comprising a computer readable storage medium having program instructions embodied therewith, the program instructions executable by the computer system to cause the computer system to perform the method, comprising: extracting a netlist and a first layout of the semiconductor chip; receiving data from the netlist and the first layout comprising parameters defining the properties of the transistors as well as a connectivity of the transistors; based on the data from the first layout detecting power connections for each transistor of the first layout and tracing signal connections and shared contacts for each transistor of the first layout; establishing a permute state for each transistor of the first layout; defining transistor pcells from the data and the permute state for each transistor; and placing the transistor pcells in the first layout and removing the flat transistor shapes from the first layout.

According to an embodiment of the invention translation of flat transistor layouts into pcell layouts may be facilitated and with this allows a faster maintenance of transistor layouts. Favorably costs for the design process of a semiconductor chip may be reduced.

Further, a data processing system for execution of a data processing program comprising computer readable program instructions for performing the method is proposed.

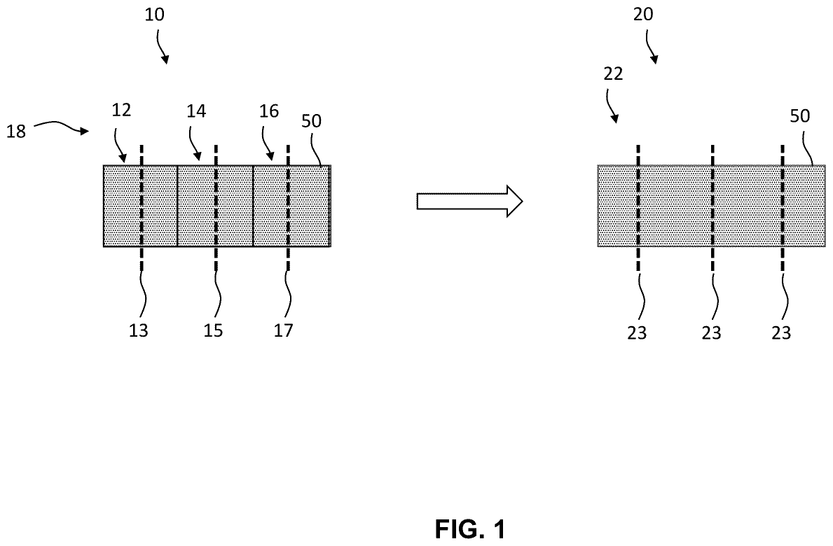

FIG. 1 depicts grouping neighbouring gate electrodes 13, 15, 17 of multi-gate flat transistor shapes 12, 14, 16 of a netlist of a first layout 10 by a single transistor pcell 22 with a corresponding number of gate electrodes 23 in a second layout 20 according to an embodiment of the invention.

According to the computer implemented method flat transistor shapes 12, 14, 16 are translated into a transistor pcell 22 during a hardware design process of a semiconductor chip 100 comprising transistors.

The method uses an extracted netlist and a first layout 10 as input and replaces flat transistor shapes 12, 14, 16 in the first layout 10 by a transistor pcell 22. The first layout 10 exhibits flat transistor shapes 12, 14, 16 with gate electrodes 13, 15, 17 on a gate oxide 50.

Data is received from the netlist. Thus, the extracted netlist is used to get the transistor properties such as position, transistor type, fins/finger and connectivity such as gate, drain, source net connection.

The first layout 10 is used to detect transistor power connections and to trace transistor signal connections in order to establish the permute state of the transistor.

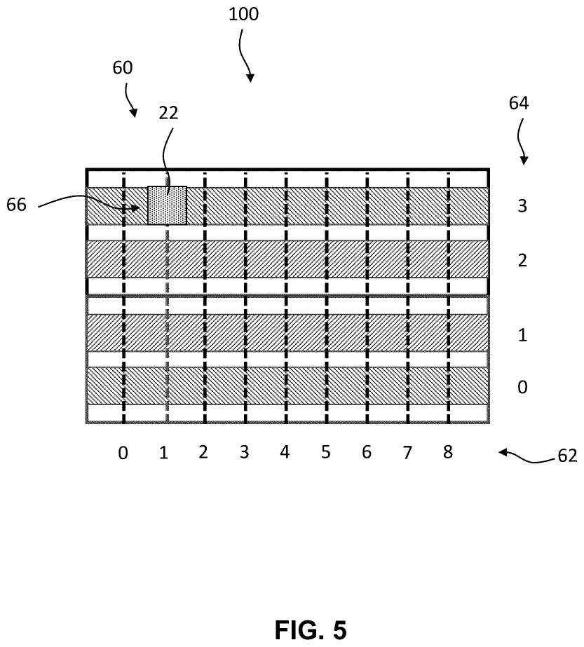

Since flat transistors shapes 12, 14, 16 are represented by single fingers, the gate electrodes 13, 15, 17, in the extracted netlist neighbouring fingers 13, 15, 17 are grouped and are represented by a single pcell instance 22 with a corresponding number of fingers, the gate electrodes 23, as a pcell parameter. For converting single fingers 13, 15, 17 of a flat transistor shape 12, 14, 16 into a multi-finger transistor pcell 22, it is sufficient to know the position of the flat transistor shapes 12, 14, 16. To be able to group flat transistor shapes 12, 14, 16 into a single transistor pcell 22, the single finger flat transistor shapes 12, 14, 16 must be in the same row and in a neighboured column of a matrix-like positioning of the transistor pcell 22 representing the transistors (e.g., see FIG. 5) and have the same source, drain, and gate connections.

In particular, neighbouring flat transistor shapes 12, 14, 16 with a same base name 18 are grouped into a single transistor pcell 22.

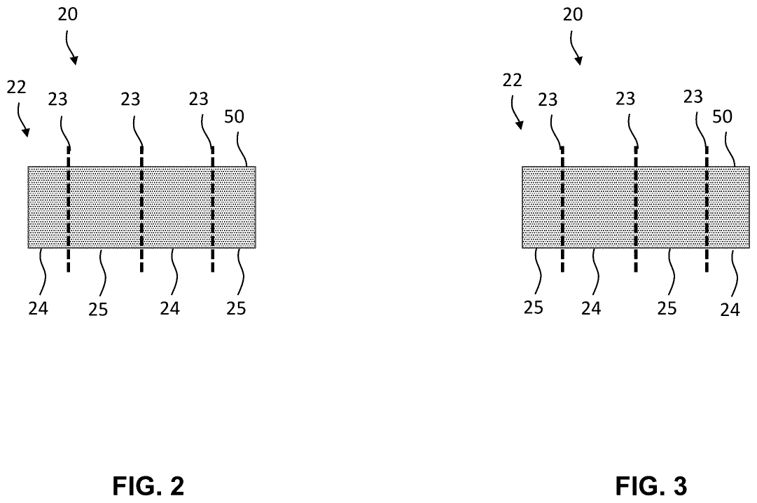

FIG. 2 depicts a first permute state for a transistor pcell 22 according to an embodiment of the invention. FIG. 3 depicts a second permute state for a transistor pcell 22.

A permute state for each transistor of the first layout 10 is established. The transistor pcells 22 are defined from the data and the permute state for each transistor. The transistor pcells 22 are placed in the first layout 10 and the flat transistor shapes 12, 14, 16 are removed from the first layout 10.

In the permute states of the transistor source electrodes 24 and drain electrodes 25 are arranged in an alternating sequence. In FIG. 2 the transistor is laid out with a source electrode 24 as a left most contact whereas in FIG. 3 the transistor is laid out with a drain electrode 25 as a left most contact.

In an alternative embodiment of the invention, the flat transistor shapes 12, 14, 16 in the first layout 10 may be replaced by transistor pcells 22 and the replacement may be stored in a second layout 20.

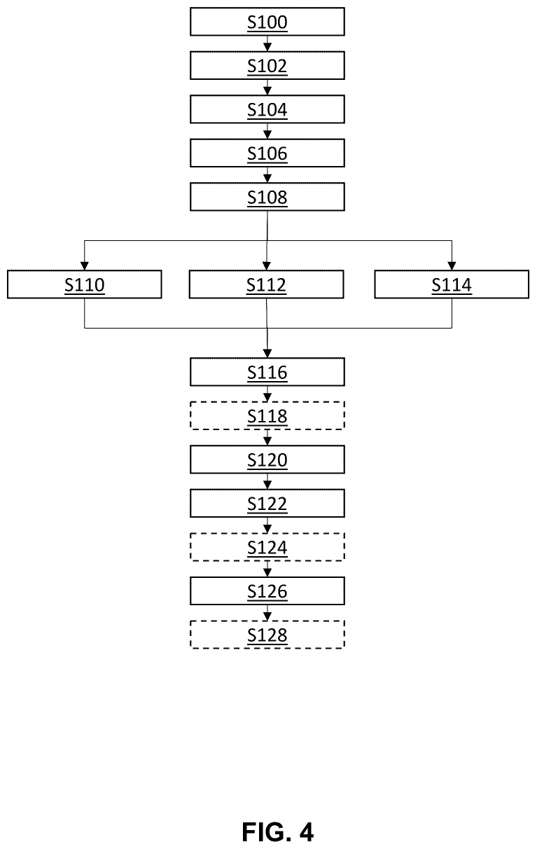

FIG. 4 depicts a flow chart of the computer implemented method for translating flat transistor shapes 12, 14, 16 into transistor pcells 22 during a hardware design process of a semiconductor chip comprising transistors according to embodiments of the present disclosure.

In operation S100, layout properties are retrieved from a first layout 10.

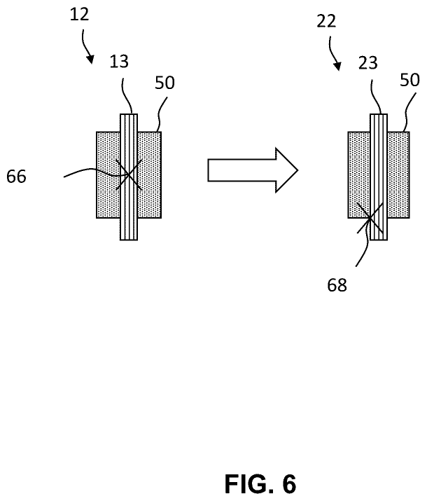

In operation S102, the transistor properties, such as geometrical coordinates, transistor type, number of fins, are retrieved from the extracted netlist. Parameters defining the properties of the transistor may comprise at least one of a position 66 (see FIG. 6) of the transistor in the first layout, a transistor type, a number of fins, a channel width, a sheet width.

In operation S104, geometrical coordinates of a power net are retrieved from the first layout 10.

In operation S106, gate, drain, source connections are retrieved from the extracted netlist. The connectivity of a transistor may at least comprise net connections of a gate electrode 23, and/or a drain electrode 25, and/or a source electrode 24 of the transistor.

In operation S108, transistor coordinates are translated into a matrix according to columns 62 and rows 64 (see FIG. 5).

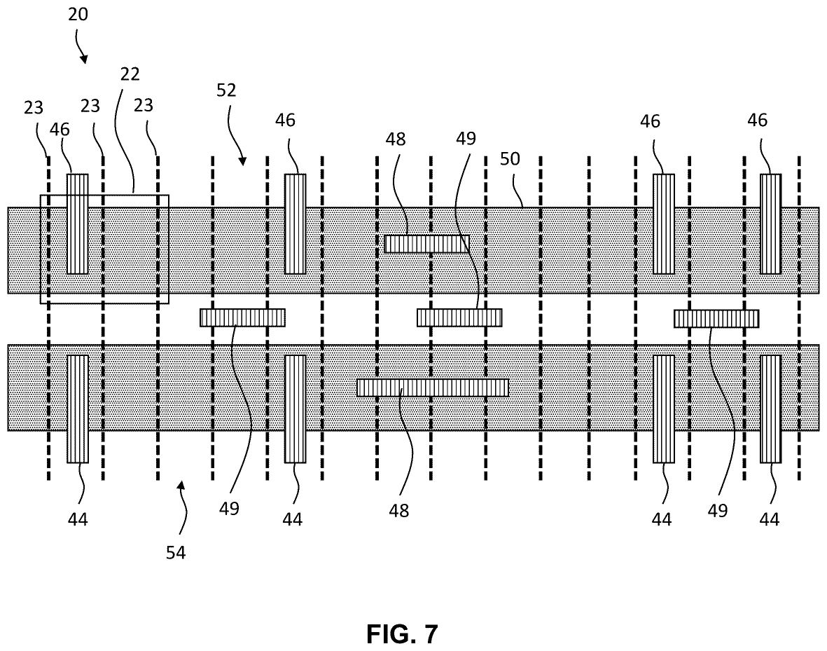

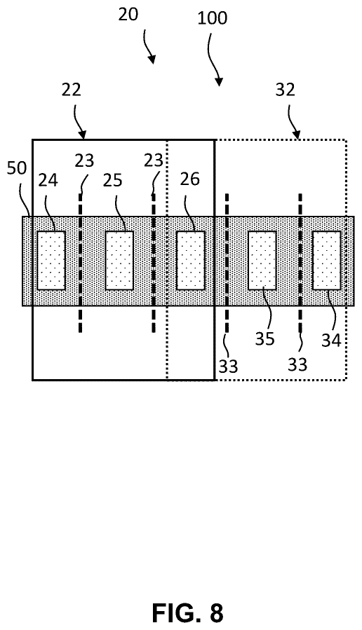

In operations S110, S112, and S114, alternatives for detection of the permute state of the transistor are executed. Detecting the permute state for each transistor pcell 22 of the first layout may comprise assigning a source electrode 24 or a drain electrode 25 as a left contact of a gate electrode 23 based on at least one of power connections 44, 46 (see FIG. 7), shared contacts 24, 26 (see FIG. 8), or net tracing in the first layout.

In operation S110, a source electrode 24 or a drain electrode 25 is assigned as a left contact, based on a power net. In an alternative operation S112, a source electrode 24 or a drain electrode 25 is assigned as a left contact, based on shared contacts. In another alternative operation S114, a source electrode 24 or a drain electrode 25 is assigned as a left contact, based on a net tracing in the first layout 10.

In operation S116, neighbouring transistors 1 in the same row 64 (see FIG. 5) with a same base name 18 are grouped.

In an optional operation S118, dummy transistors may be removed.

In operation S120, the transistor pcells 22 are generated in the first layout 10. Coordinates of the transistor pcells 22 are translated.

In operation S122, the connectivity and the permute state are applied to the transistor pcells 22 in the first layout 10.

In an optional operation S124, a transistor correspondence may be set between the first layout 10 and the schematic topology of the semiconductor chip.

In operation S126, flat transistor shapes 12, 14, 16 are removed from the first layout 10. Flat transistor shapes 12, 14, 16 in the first layout 10 are replaced by transistor pcells 22, wherein the replacement may be stored in a second layout 20. Alternatively, the first layout 10 may still be kept.

In an optional operation S128, a shape connectivity may be set. The shape connectivity is set by routing the transistor pcells 22. In design frameworks there are options for propagating the connectivity of instance pins and cell pins to shapes. The shapes of routings remain geometrically the same, only a so called “net property” will be assigned to existing shapes.

In embodiments, the second layout 20 may replace the first layout 10.

FIG. 5 depicts translating a position of a transistor pcell 22 into a matrix 60 comprising columns 62 and rows 64 according to an embodiment of the invention. Here a position 66 of a transistor pcell 22 is translated into a specific column 62 and a specific row 64 of the matrix 60. Thus, the transistor, being represented by the transistor pcell 22, further may be referred to with a position of column 1, row 3.

FIG. 6 depicts performing a coordinate translation of a transistor pcell 22 relative to a position of a gate electrode 23 according to embodiments of the present disclosure.

According to the example shown in FIG. 6, an origin of a coordinate system of a transistor pcell 22 is translated from a center position 66 on a gate electrode 13 of a flat transistor shape 12 to a lower left corner position 68 of a gate electrode 23 of a transistor pcell 22. This new position 68 of the coordinate system of the transistor pcell 22 may be used as a reference for further steps in the design process.

FIG. 7 depicts power connections 44, 46 of a transistor pcell layout 20, according to embodiments of the present disclosure.

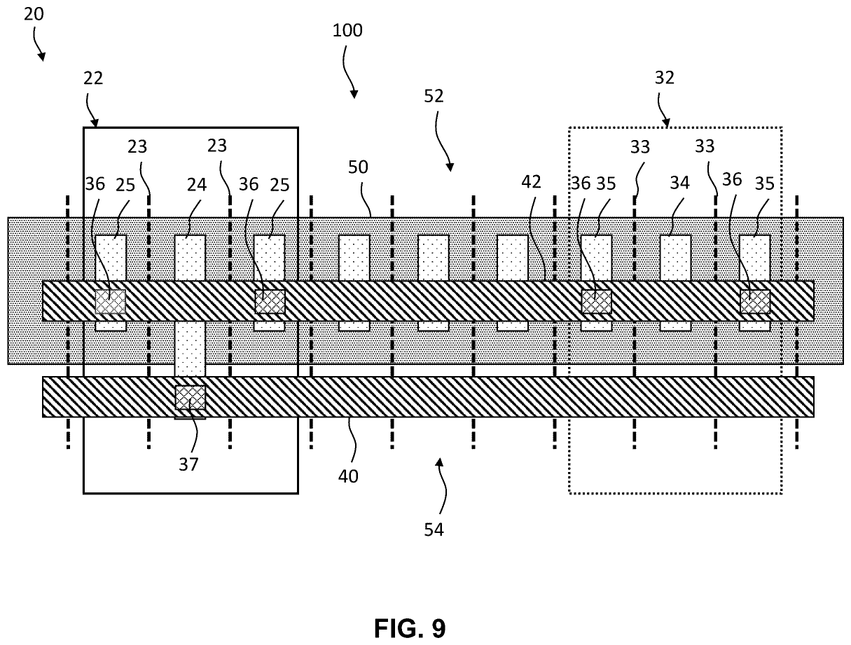

In embodiments, it may be checked, at a source-drain connection, if there is a power connection 44, 46 to a power line 40 (see FIG. 9) at a top boundary 52 or a bottom boundary 54 of the transistor pcell 22. The power connections 44, 46 may be connected to power lines 40, not shown in FIG. 7 but depicted in FIG. 9.

Further, in FIG. 7, a number of possible transistor pcells are to be seen in the pcell layout 20. One transistor pcell 22 representing a single transistor is highlighted by the rectangle in FIG. 7 comprising three gate electrodes 23.

FIG. 8 depicts configuring a shared contact 26 between two transistors pcells 22 and 32 with a same net connection, according to embodiments of the present disclosure. The first transistor pcell 22 comprises two gate electrodes 23, a drain electrode 25 and two source electrodes 24 (one source electrode being shared contact 26). The second transistor pcell 22 shares one of the source electrodes (shared contact 26) and further comprises a further source electrode 34, a drain electrode 35 and two gate electrodes 33.

FIG. 9 depicts tracing signal connections comprising tracing physical shapes to get connected transistor contacts, according to embodiments of the present disclosure.

In FIG. 9, a number of possible transistor pcells are to be seen in the pcell layout 20. Two transistor pcells 22 and 32 representing respective transistors with corresponding gate electrodes 23 and 33, source electrodes 24 and 34, and two drain electrodes 25 and 35, are highlighted by respective rectangles. The drain electrodes 25, 35 of the respective transistors (e.g., transistor pcells 22 and 32) are connected to a signal line 42 at contact areas 36, whereas the source electrode 24 of the first transistor (e.g., transistor pcell 22) is connected to a power line 40 at a contact area 37. The power line 40 may correspond to a negative voltage VSS or a ground VDD. Power lines 40 may be fed from a top boundary 52 or a bottom boundary 54, as shown in FIG. 9.

In embodiments, a semiconductor chip 100 for a computer system 212 comprising a plurality of transistors (e.g., transistor pcells 22 and 32) may be designed by a computer implemented method for translating flat transistor shapes 12, 14, 16 into transistor pcells 22, 32 during a hardware design process according to the described techniques.

Each transistor pcell 22, 32 may be configured with a source electrode 24, 34 or a drain electrode 25, 35 being assigned as a left contact of a gate electrode 23, 33 based on at least one of power connections 44, 46, shared contacts 26, or net tracing in the first layout.

Drain electrodes 25, 35 and source electrodes 24, 34 of the transistor pcells 22, 32 may be placed in an alternating sequence.

Neighbouring flat transistor shapes 12, 14, 16 with a same base name 18 may be grouped into a single transistor pcell 22, 32.

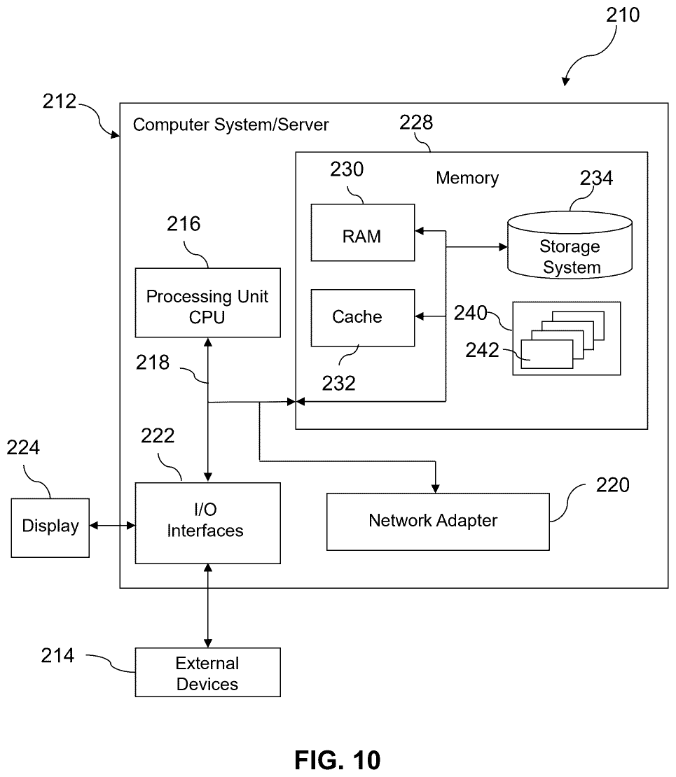

FIG. 10 depicts an example embodiment of a data processing system 210 for executing a method according to the invention.

A computer system 212 for translating flat transistor shapes 12, 14, 16 into transistor pcells 22, 32 during a hardware design process of a semiconductor chip 100 comprising transistors comprising a computer processing unit 216 storing computer executable instructions may be used to perform the method according to an embodiment of the invention.

A computer program product may be used on the data processing system 210 for translating flat transistor shapes 12, 14, 16 into transistor pcells 22, 32 during a hardware design process of a semiconductor chip 100 comprising transistors the computer program product comprising a computer readable storage medium having program instructions embodied therewith, the program instructions executable by the computer system 212 to cause the computer system 212 to perform the method according to embodiments of the present disclosure.

Referring now to FIG. 10, a schematic of an example of a data processing system 210 is shown. Data processing system 210 is only one example of a suitable data processing system and is not intended to suggest any limitation as to the scope of use or functionality of embodiments of the invention described herein. Regardless, data processing system 210 is capable of being implemented and/or performing any of the functionality set forth herein above.

In data processing system 210 there is a computer system/server 212, which is operational with numerous other general-purpose or special-purpose computing system environments or configurations. Examples of well-known computing systems, environments, and/or configurations that may be suitable for use with computer system/server 212 include, but are not limited to, personal computer systems, server computer systems, thin clients, thick clients, handheld or laptop devices, multiprocessor systems, microprocessor-based systems, set top boxes, programmable consumer electronics, network PCs, minicomputer systems, mainframe computer systems, and distributed cloud computing environments that include any of the above systems or devices, and the like.

Computer system/server 212 may be described in the general context of computer system executable instructions, such as program modules, being executed by a computer system. Generally, program modules may include routines, programs, objects, components, logic, data structures, and so on that perform particular tasks or implement particular abstract data types. Computer system/server 212 may be practiced in distributed cloud computing environments where tasks are performed by remote processing devices that are linked through a communications network. In a distributed cloud computing environment, program modules may be located in both local and remote computer system storage media including memory storage devices.

As shown in FIG. 10, computer system/server 212 in data processing system 210 is shown in the form of a general-purpose computing device. The components of computer system/server 212 may include, but are not limited to, one or more processors or processing units 216, a system memory 228, and a bus 218 that couples various system components including system memory 228 to processor 216.

Bus 218 represents one or more of any of several types of bus structures, including a memory bus or memory controller, a peripheral bus, an accelerated graphics port, and a processor or local bus using any of a variety of bus architectures. By way of example, and not limitation, such architectures include Industry Standard Architecture (ISA) bus, Micro Channel Architecture (MCA) bus, Enhanced ISA (EISA) bus, Video Electronics Standards Association (VESA) local bus, and Peripheral Component Interconnect (PCI) bus.

Computer system/server 212 typically includes a variety of computer system readable media. Such media may be any available media that is accessible by computer system/server 212, and it includes both volatile and non-volatile media, removable and non-removable media.

System memory 228 can include computer system readable media in the form of volatile memory, such as random access memory (RAM) 230 and/or cache memory 232. Computer system/server 212 may further include other removable/non-removable, volatile/non-volatile computer system storage media. By way of example only, storage system 234 can be provided for reading from and writing to a non-removable, non-volatile magnetic media (not shown and typically called a “hard drive”). Although not shown, a magnetic disk drive for reading from and writing to a removable, non-volatile magnetic disk (e.g., a “floppy disk”), and an optical disk drive for reading from or writing to a removable, non-volatile optical disk such as a CD-ROM, DVD-ROM or other optical media can be provided. In such instances, each can be connected to bus 218 by one or more data media interfaces. As will be further depicted and described below, memory 228 may include at least one program product having a set (e.g., at least one) of program modules that are configured to carry out the functions of embodiments of the invention.

Program/utility 240, having a set (at least one) of program modules 242, may be stored in memory 228 by way of example, and not limitation, as well as an operating system, one or more application programs, other program modules, and program data. Each of the operating system, one or more application programs, other program modules, and program data or some combination thereof, may include an implementation of a networking environment. Program modules 242 generally carry out the functions and/or methodologies of embodiments of the invention as described herein.

Computer system/server 212 may also communicate with one or more external devices 214 such as a keyboard, a pointing device, a display 224, etc.; one or more devices that enable a user to interact with computer system/server 212; and/or any devices (e.g., network card, modem, etc.) that enable computer system/server 212 to communicate with one or more other computing devices. Such communication can occur via Input/Output (I/O) interfaces 222. Still yet, computer system/server 212 can communicate with one or more networks such as a local area network (LAN), a general wide area network (WAN), and/or a public network (e.g., the Internet) via network adapter 220. As depicted, network adapter 220 communicates with the other components of computer system/server 212 via bus 218. It should be understood that although not shown, other hardware and/or software components could be used in conjunction with computer system/server 212. Examples, include, but are not limited to: microcode, device drivers, redundant processing units, external disk drive arrays, RAID systems, tape drives, and data archival storage systems, etc.

The present invention may be a system, a method, and/or a computer program product. The computer program product may include a computer readable storage medium (or media) having computer readable program instructions thereon for causing a processor to carry out aspects of the present invention.

The computer readable storage medium can be a tangible device that can retain and store instructions for use by an instruction execution device. The computer readable storage medium may be, for example, but is not limited to, an electronic storage device, a magnetic storage device, an optical storage device, an electromagnetic storage device, a semiconductor storage device, or any suitable combination of the foregoing. A non-exhaustive list of more specific examples of the computer readable storage medium includes the following: a portable computer diskette, a hard disk, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon, and any suitable combination of the foregoing. A computer readable storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

Computer readable program instructions described herein can be downloaded to respective computing/processing devices from a computer readable storage medium or to an external computer or external storage device via a network, for example, the Internet, a local area network, a wide area network and/or a wireless network. The network may comprise copper transmission cables, optical transmission fibers, wireless transmission, routers, firewalls, switches, gateway computers and/or edge servers. A network adapter card or network interface in each computing/processing device receives computer readable program instructions from the network and forwards the computer readable program instructions for storage in a computer readable storage medium within the respective computing/processing device.

Computer readable program instructions for carrying out operations of the present invention may be assembler instructions, instruction-set-architecture (ISA) instructions, machine instructions, machine dependent instructions, microcode, firmware instructions, state-setting data, or either source code or object code written in any combination of one or more programming languages, including an object oriented programming language such as Smalltalk, C++ or the like, and conventional procedural programming languages, such as the “C” programming language or similar programming languages. The computer readable program instructions may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider). In some embodiments, electronic circuitry including, for example, programmable logic circuitry, field-programmable gate arrays (FPGA), or programmable logic arrays (PLA) may execute the computer readable program instructions by utilizing state information of the computer readable program instructions to personalize the electronic circuitry, in order to perform aspects of the present invention.

Aspects of the present invention are described herein with reference to flowchart illustrations and/or block diagrams of methods, apparatus (systems), and computer program products according to embodiments of the invention. It will be understood that each block of the flowchart illustrations and/or block diagrams, and combinations of blocks in the flowchart illustrations and/or block diagrams, can be implemented by computer readable program instructions.

These computer readable program instructions may be provided to a processor of a general-purpose computer, special-purpose computer, or other programmable data processing apparatus to produce a machine, such that the instructions, which execute via the processor of the computer or other programmable data processing apparatus, create means for implementing the functions/acts specified in the flowchart and/or block diagram block or blocks. These computer readable program instructions may also be stored in a computer readable storage medium that can direct a computer, a programmable data processing apparatus, and/or other devices to function in a particular manner, such that the computer readable storage medium having instructions stored therein comprises an article of manufacture including instructions which implement aspects of the function/act specified in the flowchart and/or block diagram block or blocks.

The computer readable program instructions may also be loaded onto a computer, other programmable data processing apparatus, or other device to cause a series of operational steps to be performed on the computer, other programmable apparatus or other device to produce a computer implemented process, such that the instructions which execute on the computer, other programmable apparatus, or other device implement the functions/acts specified in the flowchart and/or block diagram block or blocks.

The flowchart and block diagrams in the Figures illustrate the architecture, functionality, and operation of possible implementations of systems, methods, and computer program products according to various embodiments of the present invention. In this regard, each block in the flowchart or block diagrams may represent a module, segment, or portion of instructions, which comprises one or more executable instructions for implementing the specified logical function(s). In some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special-purpose hardware-based systems that perform the specified functions or acts or carry out combinations of special-purpose hardware and computer instructions.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

Further exemplary embodiments of the present disclosure are set out in the following numbered clauses:

Numbered clause 1: A computer implemented method for translating flat transistor shapes (12, 14, 16) into transistor pcells (22, 32) during a hardware design process of a semiconductor chip (100) comprising transistors, the method comprising
extracting a netlist and a first layout (10) of the semiconductor chip (100);
receiving data from the netlist and the first layout (10) comprising parameters defining the properties of the transistors as well as a connectivity of the transistors;
based on the data from the first layout (10) detecting power connections (44, 46) for each transistor of the first layout (10) and tracing signal connections and shared contacts (26) for each transistor of the first layout (10);
establishing a permute state for each transistor of the first layout (10);
defining transistor pcells (22, 32) from the data and the permute state for each transistor;
placing the transistor pcells (22, 32) in the first layout (10) and removing the flat transistor shapes (12, 14, 16) from the first layout (10).

Numbered clause 2: The method according to clause 1, further performing a replacement of the flat transistor shapes (12, 14, 16) in the first layout (10) by transistor pcells (22, 32), wherein the replacement is stored in a second layout (20).

Numbered clause 3: The method according to clause 2, wherein the second layout (20) replaces the first layout (10).

Numbered clause 4: The method according to any one of the preceding clauses, wherein parameters defining the properties of the transistor comprise at least one of a position (66) of the transistor in the first layout (10), a transistor type, a number of gate fingers, a channel width, a number of fins, a sheet width, a width to length ratio.

Numbered clause 5: The method according to any one of the preceding clauses, wherein the connectivity of a transistor at least comprises net connections of a gate electrode (23, 33), and/or a drain electrode (25, 35), and/or a source electrode (24, 34) of the transistor.

Numbered clause 6: The method according to any one of the preceding clauses, further detecting the permute state for each transistor pcell (22, 32) of the first layout (10) comprising assigning a source electrode (24, 34) or a drain electrode (25, 35) as a left contact of a gate electrode (23, 33) based on at least one of
power connections (44, 46);
shared contacts (26);
net tracing in the first layout.

Numbered clause 7: The method according to any one of the preceding clauses, further placing drain electrodes (25, 35) and source electrodes (24, 34) of the transistor pcells (22, 32) in an alternating sequence.

Numbered clause 8: The method according to any one of the preceding clauses, further grouping and representing neighboring gate electrodes (13, 15, 17) of multi-gate flat transistor shapes (12, 14, 16) of the netlist by a single transistor pcell (22, 32) with a corresponding number of gate electrodes (23).

Numbered clause 9: The method according to any one of the preceding clauses, further translating a position (66) of a transistor pcell (22, 32) into a matrix (60) comprising columns (62) and rows (64).

Numbered clause 10: The method according to any one of the preceding clauses, further performing a coordinate translation of a transistor pcell (22, 32) relative to a position of a gate electrode (23, 33), in particular, defining a coordinate origin (68) of a transistor pcell (22, 32) in a lower left corner position (66) of a gate electrode (23, 33).

Numbered clause 11: The method according to any one of the preceding clauses, further grouping neighboring flat transistor shapes (12, 14, 16) with a same base name (18) into a single transistor pcell (22, 32).

Numbered clause 12: The method according to any one of the preceding clauses, further removing dummy transistors in the first layout (10).

Numbered clause 13: The method according to any one of the preceding clauses, further setting a transistor correspondence between the first layout (10) and schematic topology of the semiconductor chip (100).

Numbered clause 14: The method according to any one of the preceding clauses, wherein a shape connectivity is set by routing the transistor pcells (22, 32).

Numbered clause 15: The method according to any one of the preceding clauses, further checking at a source-drain connection if there is a power connection (44, 46) to a power line (40, 42) at a top boundary (52) or a bottom boundary (54) of the transistor pcell (22, 32).

Numbered clause 16: The method according to any one of the preceding clauses, further configuring the shared contact (26) between two transistors pcells (22, 32) with a same net connection.

Numbered clause 17: The method according to any one of the preceding clauses, wherein tracing signal connections comprises tracing physical shapes to get connected transistor contacts.

Numbered clause 18: A semiconductor chip (100) for a computer system (212) comprising a plurality of transistors, designed by a computer implemented method for translating flat transistor shapes (12, 14, 16) into transistor pcells (22, 32) during a hardware design process according to any one of the preceding clauses.

Numbered clause 19: The semiconductor chip according to clause 18, wherein each transistor pcell (22, 32) is configured with a source electrode (24, 34) or a drain electrode (25, 35) is assigned as a left contact of a gate electrode (23, 33) based on at least one of
power connections (44, 46);
shared contacts (26);
net tracing in the first layout.

Numbered clause 20: The semiconductor chip according to clause 18 or 19, wherein drain electrodes (25, 35) and source electrodes (24, 34) of the transistor pcells (22, 32) are placed in an alternating sequence.

Numbered clause 21: The semiconductor chip according to any one of the clauses 18 to 20, wherein neighbouring flat transistor shapes (12, 14, 16) with a same base name (18) are grouped into a single transistor pcell (22, 32).

Numbered clause 22: A computer system (212) for translating flat transistor shapes (12, 14, 16) into transistor pcells (22, 32) during a hardware design process of a semiconductor chip (100) comprising transistors, comprising a computer processing unit (216) storing computer executable instructions to perform the method according to any one of the clauses 1 to 17, comprising:
extracting a netlist and a first layout (10) of the semiconductor chip (100);
receiving data from the netlist and the first layout (10) comprising parameters defining the properties of the transistors as well as a connectivity of the transistors (1, 2);
based on the data from the first layout (10) detecting power connections (44, 46) for each transistor of the first layout (10) and tracing signal connections and shared contacts (26) for each transistor (1, 2) of the first layout (10);
establishing a permute state for each transistor of the first layout (10);
defining transistor pcells (22, 32) from the data and the permute state for each transistor (1, 2);
placing the transistor pcells (22, 32) in the first layout (10) and removing the flat transistor shapes (12, 14, 16) from the first layout (10).

Numbered clause 23: A computer program product for translating flat transistor shapes (12, 14, 16) into transistor pcells (22, 32) during a hardware design process of a semiconductor chip (100) comprising transistors,
the computer program product comprising a computer readable storage medium having program instructions embodied therewith, the program instructions executable by the computer system (212) to cause the computer system (212) to perform the method according to any one of the clauses 1 to 17 comprising:
   extracting a netlist and a first layout (10) of the semiconductor chip (100);
   receiving data from the netlist and the first layout (10) comprising parameters defining the properties of the transistors as well as a connectivity of the transistors (1, 2);
   based on the data from the first layout (10) detecting power connections (44, 46) for each transistor (1, 2) of the first layout (10) and tracing signal connections and shared contacts (26) for each transistor of the first layout (10);
   establishing a permute state for each transistor of the first layout (10);
   defining transistor pcells (22, 32) from the data and the permute state for each transistor (1, 2);
   placing the transistor pcells (22, 32) in the first layout (10) and removing the flat transistor shapes (12, 14, 16) from the first layout (10).

Numbered clause 24: A data processing system (210) for execution of a data processing program (240) comprising computer readable program instructions for performing the method according to any one of the clauses 1 to 17.

1. A computer implemented method for translating flat transistor shapes into transistor parameterized cells (pcells) during a hardware design process of a semiconductor chip comprising transistors, the method comprising:
extracting a netlist and a first layout of the semiconductor chip, wherein the netlist and the first layout comprise parameters defining properties of transistors of the first layout and connectivity of the transistors of the first layout;
detecting, based on the netlist and the first layout, power connections, tracing signal connections, and shared contacts of respective ones of transistors of the first layout;
establishing a permute state of respective ones of transistors of the first layout;
defining respective ones of transistor pcells based on the permute state for respective transistors of the first layout;
removing flat transistor shapes of respective ones of the transistors within the first layout and placing respective ones of the transistor pcells into the first layout.

2. The method according to claim 1, where removing flat transistor shapes of respective ones of the transistors within the first layout and placing respective ones of the transistor pcells into the first layout is a replacement, wherein the replacement generates a second layout.

3. The method according to claim 2, wherein the second layout replaces the first layout.

4. The method according to claim 1, wherein parameters defining the properties of the transistors comprise at least one of a position of transistors in the first layout, a transistor type, a number of gate fingers, a channel width, a number of fins, a sheet width, and a width to length ratio.

5. The method according to claim 1, wherein connectivity of a transistor of the transistors at least comprises net connections of a gate electrode, a drain electrode, and a source electrode of the transistor.

6. The method according to claim 1, wherein establishing the permute state for respective ones of transistors of the first layout comprises assigning a source electrode as a left contact of a gate electrode based on at least one of power connections, shared contacts, and net tracing in the first layout.

7. The method according to claim 1, further comprising placing drain electrodes and source electrodes of respective ones of transistor pcells in an alternating sequence.

8. The method according to claim 1, further comprising grouping and representing neighboring gate electrodes of a set of multi-gate flat transistor shapes of a first transistor of the netlist by a first transistor pcell with a corresponding number of gate electrodes.

9. The method according to claim 1, further comprising translating a position of a first transistor pcell into a matrix comprising columns and rows.

10. The method according to claim 1, further comprising performing a coordinate translation of a first transistor pcell relative to a position of a gate electrode.

11. The method according to claim 1, further comprising grouping neighboring flat transistor shapes with a same base name of a first transistor into a single transistor pcell.

12. The method according to claim 1, further comprising removing dummy transistors in the first layout.

13. The method according to claim 1, further comprising setting a transistor correspondence between the first layout and schematic topology of the semiconductor chip.

14. The method according to claim 1, wherein a shape connectivity is set by routing the transistor pcells.

15. The method according to claim 1, further comprising checking at a source-drain connection if there is a power connection to a power line at a boundary of a first transistor pcell of the transistor pcells.

16. The method according to claim 1, further comprising configuring a shared contact between a first transistor pcell and a second transistor pcell with a same net connection.

17. The method according to claim 1, wherein tracing signal connections comprises tracing physical shapes to obtain connected transistor contacts.

18. A semiconductor chip for a computer system comprising transistors, designed by the computer implemented method for translating flat transistor shapes into transistor pcells during the hardware design process according to claim 1.

19. The semiconductor chip according to claim 18, wherein respective ones of the transistor pcells are configured with a source electrode drain electrode assigned as a left contact of a gate electrode based on at least one of power connections, shared contacts, and net tracing in the first layout.

20. The semiconductor chip according to claim 18, wherein drain electrodes and source electrodes of respective ones of the transistor pcells are placed in an alternating sequence.

21. The semiconductor chip according to claim 18, wherein neighboring flat transistor shapes with a same base name are grouped into a first transistor pcell.

22. A computer system comprising:
a processor set;
one or more computer-readable storage media; and
program instructions stored on the one or more storage media to cause the processor set to perform operations for translating flat transistor shapes into transistor parameterized cells (pcells) during a hardware design process of a semiconductor chip comprising:
extracting a netlist and a first layout of the semiconductor chip, wherein the netlist and the first layout comprise parameters defining properties of transistors of the first layout and connectivity of the transistors of the first layout;
detecting, based on the netlist and the first layout, power connections, tracing signal connections, and shared contacts of respective ones of transistors of the first layout;
establishing a permute state of respective ones of transistors of the first layout;
defining respective ones of transistor pcells based on the permute state of respective transistors of the first layout;
removing flat transistor shapes of respective ones of the transistors within the first layout and placing respective ones of the transistor pcells into the first layout. comprising:

23. A computer program product comprising:
one or more computer-readable storage media; and
program instructions stored on the one or more storage media to perform operations for translating flat transistor shapes into transistor parameterized cells (pcells) during a hardware design process of a semiconductor chip comprising transistors comprising:
extracting a netlist and a first layout of the semiconductor chip, wherein the netlist and the first layout comprise parameters defining properties of transistors of the first layout and connectivity of the transistors of the first layout;
detecting, based on the netlist and the first layout, power connections, tracing signal connections, and shared contacts of respective ones of transistors of the first layout;
establishing a permute state of respective ones of transistors of the first layout;
defining respective ones of transistor pcells based on the permute state of respective transistors of the first layout;
removing flat transistor shapes of respective ones of the transistors within the first layout and placing respective ones of the transistor pcells into the first layout.

24. A computer implemented method for translating flat transistor shapes of a first transistor into a first parameterized cells (pcells), the method comprising:
extracting a netlist and a first layout of a semiconductor chip, wherein the netlist and the first layout comprise parameters defining properties of the first transistor of the first layout and connectivity of the first transistor of the first layout;
detecting, based on the netlist and the first layout, power connections, tracing signal connections, and shared contacts of the first transistor of the first layout;
establishing a permute state of the first transistor of the first layout;
defining a first transistor pcell based on the permute state of the first transistor of the first layout;
removing flat transistor shapes of the first transistor from the first layout and placing the first transistor pcell into the first layout to generate a second layout.

25. The method according to claim 24, wherein connectivity of the first transistor comprises net connections of a gate electrode, a drain electrode, and a source electrode of the first transistor.
